(19) United States
(12) Patent Application Publication
(10) Pub. No.: US 2008/0129145 A1
(43) Pub. Date: Jun. 5, 2008

(54) PIEZOELECTRIC ACTUATOR AND METHOD FOR SEARCHING OPTIMAL DRIVING FREQUENCY USING THE SAME

(75) Inventors: Youn Joong Lee, Seoul (KR); Kwon Kyoung Soo, Gyeonggi-do (KR); Hwang Byoung Won, Gyeonggi-do (KR); Kwon Oh Jo, Gyeonggi-do (KR); Park Chan Woo, Gyeonggi-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., Gyunggi-do (KR)

(21) Appl. No.: 11/947,464

(22) Filed: Nov. 29, 2007

(30) Foreign Application Priority Data
Nov. 30, 2006 (KR) 10-2006-0120046

(51) Int. Cl. H01L 41/09

(52) U.S. Cl. 310/317

(57) ABSTRACT

Provided is a piezoelectric actuator for driving a piezoelectric unit having two resonance points. The piezoelectric unit includes an optimal driving frequency calculating unit that adds a delta frequency, having a constant frequency difference from a first resonant frequency of the piezoelectric unit, to a characteristic resonant frequency obtained by analyzing characteristics of the piezoelectric unit, thereby calculating an optimal driving frequency; and an FM modulating unit that is connected to the optimal driving frequency calculating unit and generates the optimal driving frequency, calculated by the optimal driving frequency calculating unit, so as to supply to the piezoelectric unit.

### CROSS-REFERENCE TO RELATED APPLICATIONS

This application claims the benefit of Korean Patent Application No. 10-2006-0120046 filed with the Korea Intellectual Property Office on Nov. 30, 2006, the disclosure of which is incorporated herein by reference.

### BACKGROUND OF THE INVENTION

1. Field of the Invention

The present invention relates to a piezoelectric actuator and a method for searching an optimal driving frequency using the same.

2. Description of the Related Art

As a camera module used in mobile phones is considered as an essential element for mobile phones, the importance of additional functions thereof is increasing. Accordingly, to implement an auto-focusing function which is widely used among the additional functions of a camera module used in mobile phones, the position of a lens section having a plurality of lenses mounted therein should be vertically moved.

To move the position of the lens section of the camera module, an actuator is used. As for the actuator, a voice-coiled actuator (VCA) and a piezoelectric actuator are commonly used.

Recently, as mobile phones are reduced in size and power consumption, a camera module and an auto-focusing module mounted on the mobile phones are also reduced in size and power consumption. Further, since the power consumption and size of the piezoelectric actuator are smaller than those of the VCA, the piezoelectric actuator is frequently used.

Further, researches on a piezoelectric actuator, in which a piezoelectric unit has two resonance points so as to easily move a lens barrel, are being carried out.

Hereinafter, a conventional piezoelectric actuator and a conventional method for searching for an optimal driving frequency will be described with reference to accompanying drawings.

FIG. 1 is a block diagram of a conventional piezoelectric actuator. FIG. 2 is a graph showing the driving frequency of a piezoelectric unit having two resonance points.

As shown in FIG. 1, the conventional piezoelectric actuator includes a control unit 110, a frequency generating unit 120, a driving frequency supply unit 130, and a comparing unit 150.

The control unit 110 is connected to the frequency generating unit 120, the driving frequency supply unit 130, and the comparing unit 150. As the driving frequency supply unit 130 is controlled by a signal compared through the comparing unit 150, a constant driving frequency is supplied to the piezoelectric unit 140.

The frequency generating unit 120 is connected to the control unit 110 and the driving frequency supply unit 130 and generates a frequency for driving the piezoelectric unit 140.

The driving frequency supply unit 130 is connected to the control unit 110, the frequency supply unit 120, and a piezoelectric unit 140 and is controlled by the control unit 110 so as to supply the driving frequency to the piezoelectric unit 140, thereby driving the piezoelectric unit 140.

The piezoelectric unit 140 is connected to the driving frequency supply unit 130 and is driven by the driving frequency supplied from the driving frequency supply unit 130 so as to vertically move a lens section having a plurality of lenses mounted therein, thereby adjusting the focus of an image which is to be photographed.

As shown in FIG. 2, the piezoelectric unit 140 has two of first and second resonant points. When the first resonant frequency corresponding to the first resonance point is applied, the piezoelectric unit 140 resonates in a lengthwise direction. When the second resonant frequency corresponding to the second resonance point is applied, the piezoelectric unit 140 resonates in a widthwise direction.

When the piezoelectric unit having the first and second resonance points is driven by a frequency at a position ‘A’ which is an intermediate frequency between the first and second resonance frequencies, the piezoelectric unit resonates in both the lengthwise direction and widthwise direction so as to vertically move the lens section by the maximum distance.

Accordingly, as the driving frequency supply unit 130 always supplies the intermediate frequency to drive the piezoelectric unit 140, the lens section can be moved the maximum distance by the resonance of the piezoelectric unit 140.

The comparator 150 is connected to the control unit 110 and the driving frequency supply unit 130 and receives the driving frequency supplied to the piezoelectric unit 140 from the driving frequency supply unit 130 so as to compare with an optimal driving frequency for optimally driving the piezoelectric unit 140. When the supplied driving frequency is not the optimal driving frequency, the comparing unit 150 supplies a corresponding comparison signal to the control unit 110.

At this time, the control unit 110 receives the comparison signal on whether or not the driving frequency supplied from the driving frequency supply unit 130 is identical to the intermediate frequency of the piezoelectric unit 140, and then controls the driving frequency supply unit 130 so as to supply a constant driving frequency to the piezoelectric unit 140.

Now, a conventional method for searching for an optimal driving frequency using the piezoelectric actuator will be described with reference to FIG. 2.

First, as shown in FIG. 2, first and second driving frequencies of the piezoelectric unit are calculated (step S210).

Then, an intermediate frequency between the first and second driving frequencies calculated in step S210 is calculated (step S220).

Next, the intermediate frequency calculated in step S220 is set to a driving frequency and is then supplied to the piezoelectric unit (step S230).

At this time, when the driving frequency supplied to the piezoelectric unit in step S230 is not the calculated intermediate frequency, the driving frequency is corrected into the intermediate frequency, and the corrected driving frequency is supplied to drive the piezoelectric unit.

For example, it is assumed that the frequency of the piezoelectric unit ranges from 300 to 350 KHz, the first resonant frequency is 330 KHz, and the second frequency is 340 KHz. In this case, an intermediate frequency to be supplied to the piezoelectric unit is 335 KHz which is an intermediate frequency between the first and second resonant frequencies.

As the intermediate frequency of 335 KHz is always supplied to the piezoelectric unit, the piezoelectric unit is driven. If the supplied driving frequency is changed into a frequency of 332 KHz, the comparing unit receives the frequency and then delivers to the control unit a comparison signal indicating that the frequency is different from the driving frequency. The control unit receiving the comparison signal controls the driving frequency supply unit so as to supply the driving frequency of 335 KHz.

However, in the conventional piezoelectric actuator and the conventional method for searching for an optimal driving frequency, when the surrounding environment and temperature of the piezoelectric unit 140 are changed, the first and second driving frequencies of the piezoelectric unit 140 are changed, so that the piezoelectric unit 140 is not normally driven. Therefore, it is difficult to precisely adjust the focus of an image.

Further, when the surrounding environment and temperature of the piezoelectric actuator are changed, the preset driving frequency is changed. Then, to set the driving frequency of the piezoelectric unit, the searching should be repeatedly performed with respect to the entire range of the driving frequency. Therefore, it takes a long time for searching the optimal driving frequency.

### SUMMARY OF THE INVENTION

An advantage of the present invention is that it provides a piezoelectric actuator and a method for searching an optimal driving frequency using the same, in which the characteristics of a resistor, an inductor, and a capacitor are analyzed so as to calculate a characteristic resonant frequency having the same characteristic as that of a first resonant frequency of the piezoelectric unit. Therefore, it is possible to drive the piezoelectric unit in a constant manner despite changes in surrounding environment and temperature.

Additional aspects and advantages of the present general inventive concept will be set forth in part in the description which follows and, in part, will be obvious from the description, or may be learned by practice of the general inventive concept.

According to an aspect of the invention, a piezoelectric actuator for driving a piezoelectric unit having two resonance points comprises an optimal driving frequency calculating unit that adds a delta frequency, having a constant frequency difference from a first resonant frequency of the piezoelectric unit, to a characteristic resonant frequency obtained by analyzing characteristics of the piezoelectric unit, thereby calculating an optimal driving frequency; and an FM modulating unit that is connected to the optimal driving frequency calculating unit and generates the optimal driving frequency, calculated by the optimal driving frequency calculating unit, so as to supply to the piezoelectric unit.

Preferably, the characteristic resonant frequency is calculated by analyzing the characteristics of a resistor, an inductor, and a capacitor of the piezoelectric unit.

Preferably, the characteristic resonant frequency of the optimal driving frequency calculating unit has the same characteristic as that of the first resonant frequency of the piezoelectric unit.

Preferably, the delta frequency is obtained by subtracting the first resonant frequency from an intermediate frequency between the first and second resonant frequencies of the piezoelectric unit.

According to another aspect of the invention, a method for searching for an optimal driving frequency for driving a piezoelectric unit having two resonance points comprises the steps of: (a) calculating an intermediate frequency between first and second resonant frequencies of the piezoelectric unit; (b) calculating a delta frequency by subtracting the first frequency from the calculated intermediate frequency; (c) calculating a characteristic resonant frequency by analyzing characteristics of the piezoelectric unit; and (d) calculating an optimal driving frequency by adding the delta frequency to the characteristic resonant frequency calculated in step (c).

Preferably, in step (c), the characteristics of a resistor, an inductor, and a capacitor of the piezoelectric unit are analyzed.

Preferably, the characteristic resonant frequency calculated in step (c) has the same characteristic as the first resonant frequency of the piezoelectric unit.

According to a further aspect of the invention,

According to a still further aspect of the invention,

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram of a conventional piezoelectric actuator;

FIG. 2 is a graph showing the driving frequency of a piezoelectric unit having two resonance points;

FIG. 3 is a flow chart sequentially showing a conventional method for searching an optimal driving frequency for driving a piezoelectric unit;

FIG. 4 is a block diagram schematically showing a piezoelectric actuator according to the invention;

FIG. 5 is a graph showing the driving frequency of a piezoelectric unit which is changed depending on changes in surrounding environment and temperature;

FIG. 6 is a graph showing a moving distance of a lens section in accordance with the driving frequency of the piezoelectric unit; and

FIG. 7 is a flow chart sequentially showing a method for searching for an optimal driving frequency using a piezoelectric actuator according to the invention.

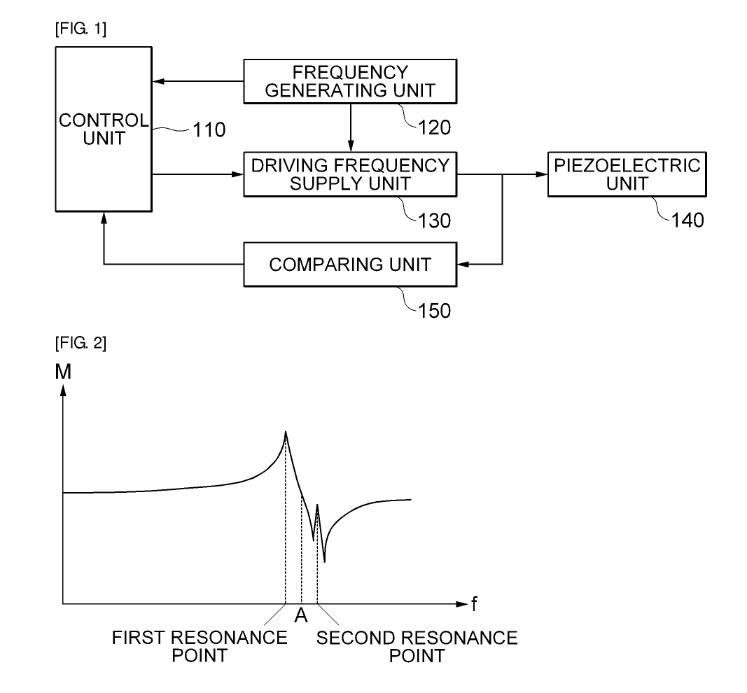

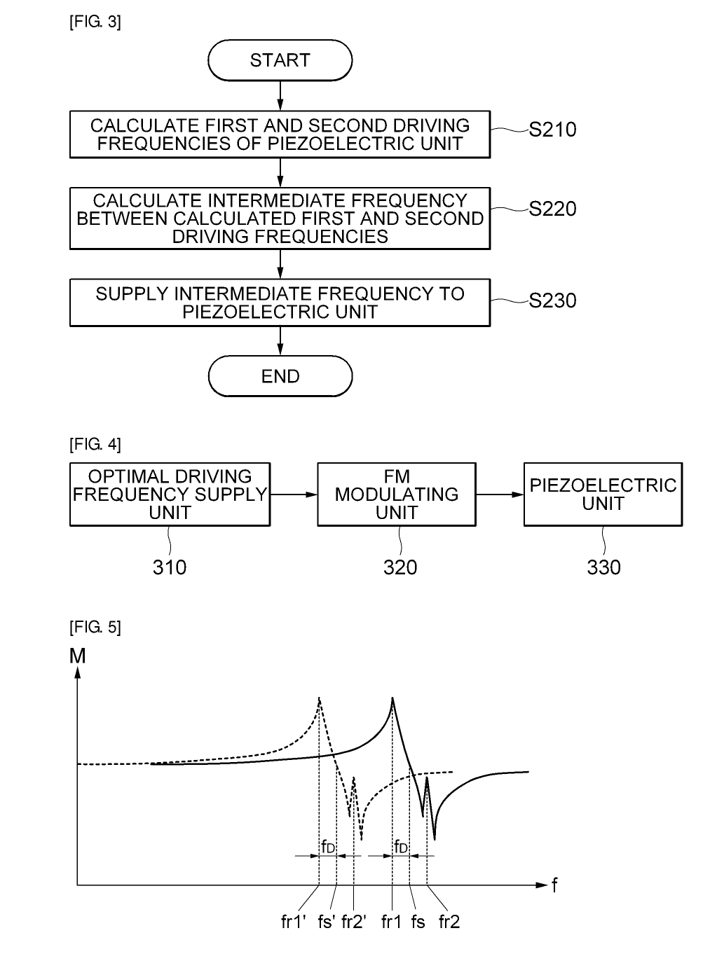

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a piezoelectric actuator and a method for searching an optimal driving frequency using the same according to the present invention will be described in detail with reference to the accompanying drawings.

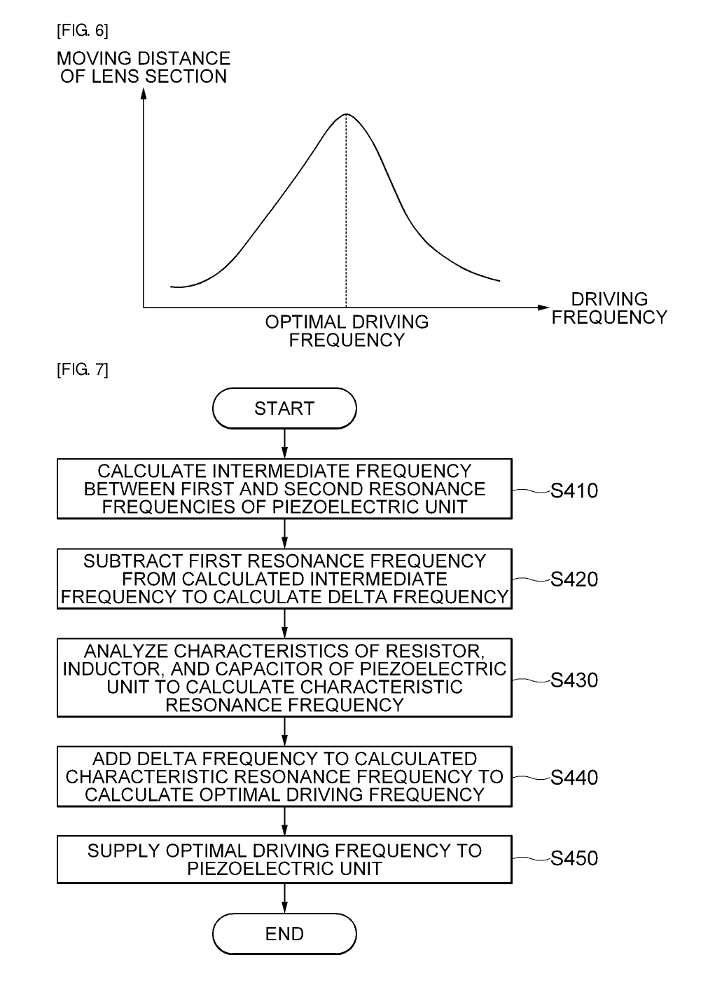

FIG. 4 is a block diagram schematically showing a piezoelectric actuator according to the invention. FIG. 5 is a graph showing the driving frequency of a piezoelectric unit which is changed depending on changes in surrounding environment and temperature. FIG. 6 is a graph showing a moving distance of a lens section in accordance with the driving frequency of the piezoelectric unit.

As shown in FIG. 4, the piezoelectric actuator includes an optimal driving frequency calculating unit 310 and an FM modulating unit 320.

As shown in FIG. 5, a piezoelectric unit 330 has two of first and second resonance points. When first and second driving frequencies fr1 and fr2 corresponding to the first and second resonance points are applied, the piezoelectric unit 330 resonates in a lengthwise or widthwise direction so as to move a lens section (not shown), thereby adjusting the focus of an image which is to be photographed.

At this time, when an intermediate frequency fs between the first and second driving frequencies fr1 and fr2 is supplied as a driving frequency for the piezoelectric unit 330, the piezoelectric unit 330 receiving the intermediate frequency fs resonates in both lengthwise and widthwise directions so as to move the lens section. As the lens section is moved by the maximum distance, the optimal driving frequency of the piezoelectric unit 330 is set to the intermediate frequency fs, as shown in FIG. 6.

To compensate for the first and second resonant frequencies fr1 and fr2 of the piezoelectric unit 330, which are changed depending on changes in surrounding environment and temperature, the optimal driving frequency calculating unit 310 analyzes the characteristics of a resistor, an inductor, and a capacitor, which indicate the characteristics of the first and second resonant frequencies fr1 and fr2, among elements composing the piezoelectric unit 330.

In accordance with the characteristic analysis on the resistor, the inductor, and capacitor, a characteristic resonant frequency is calculated, which is a frequency having the same characteristic as the first resonant frequency fr1 of the piezoelectric unit 330. At this time, since the characteristic resonant frequency is calculated in accordance with the characteristic analysis on the resistor, the inductor, and capacitor which determine the frequency characteristic of the piezoelectric unit 330, the characteristic resonant frequency is changed by the same width as the first resonant frequency fr1 of the piezoelectric unit 330 which is changed depending on changes in surrounding environment and temperature. Therefore, the characteristic resonant frequency has the same characteristic as the first resonant frequency fr is maintained.

By using the calculated characteristic resonant frequency, an optimal driving frequency for driving the piezoelectric unit 300 to the maximum moving distance can be calculated. That is, since the optimal driving frequency is the intermediate frequency fs between the first and second resonant frequencies fr1 and fr2 of the piezoelectric unit 330, the intermediate frequency fs always has a difference of delta frequency f_{D} from the first resonant frequency fr1.

At this time, although the magnitude of the intermediate frequency fs and the first resonant frequency fr1 is changed depending on changes in surrounding environment and temperature, the delta frequency f_{D} which is a difference between the two frequencies is constantly maintained at all times.

Accordingly, after the intermediate frequency fs between the first and second resonant frequencies fr1 and fr2 is calculated, the first resonant frequency fr1 is subtracted from the calculated intermediate frequency fs, thereby calculating the delta frequency f_{D}.

Further, when the first resonant frequency fr1 is added to the calculated delta frequency f_{D}, the optimal driving frequency can be calculated. Based on that, as the delta frequency f_{D} is added to the characteristic resonant frequency having the same characteristic as the first resonant frequency fr1, the same frequency as the changed optimal driving frequency of the piezoelectric unit 330 can be calculated at all times.

A signal for the driving frequency calculated by the optimal driving frequency calculating unit 310 is delivered to the FM modulating unit 320 connected to the optimal driving frequency calculating unit 310.

The FM modulating unit 320 generates the driving frequency calculated by the optimal driving frequency calculating unit 310 so as to supply to the piezoelectric unit 330. Then, the piezoelectric unit 330 can resonate at the maximum so as to be driven.

As shown in FIG. 5, if the first driving frequency fr1 is changed into a first driving frequency fr1′ due to changes in surrounding environment and temperature of the piezoelectric actuator, the characteristic resonant frequency calculated by the optimal driving frequency calculating unit 310 has the same frequency as the changed first driving frequency fr1′.

As the delta frequency f_{D} is added to the changed characteristic resonant frequency, the optimal driving frequency of the piezoelectric unit 330 can be supplied at all times. Accordingly, the lens section can be moved the maximum distance by the piezoelectric unit 330.

Further, the piezoelectric actuator according to the invention can calculate and supply the optimal driving frequency for driving the piezoelectric unit 330 by using only the optimal driving frequency calculating unit 310 and the FM modulating unit 320. Therefore, it is possible to reduce the size of the piezoelectric actuator, compared with the conventional piezoelectric actuator which is composed of the control unit, the frequency generating unit, the driving frequency supply unit, and the comparing unit.

Hereinafter, a method for searching for an optimal driving frequency using a piezoelectric actuator according to the invention will be described with reference to the accompanying drawings.

FIG. 7 is a flow chart sequentially showing a method for searching for an optimal driving frequency using a piezoelectric actuator according to the invention.

First, as shown in FIG. 7, first and second resonant frequencies of the piezoelectric unit having two resonance points are calculated. Then, an intermediate frequency between the first and second resonant frequencies is calculated (step S410).

At this time, the reason why the intermediate frequency between the first and second resonant frequencies is calculated is as follows. When the first resonant frequency is supplied to the piezoelectric unit, the piezoelectric unit resonates in a lengthwise direction. When the second resonant frequency is supplied to the piezoelectric unit, the piezoelectric unit resonates in a widthwise direction. However, when the intermediate frequency between the first and second resonant frequencies is supplied as a driving frequency to the piezoelectric unit, the piezoelectric unit resonates in both the lengthwise and widthwise directions. Therefore, a lens section can be moved the maximum distance by the resonance of the piezoelectric unit. Accordingly, the intermediate frequency between the first and second resonant frequencies is calculated.

Next, the first resonant frequency is subtracted from the intermediate frequency calculated in step S410 so as to calculate a delta frequency (step S420).

At this time, the delta frequency indicates a difference between the first resonant frequency and the intermediate frequency. When the first resonant frequency is known, the calculated delta frequency is added to the first resonant frequency so as to obtain the intermediate frequency.

After the delta frequency is calculated, the characteristics of a resistor, an inductor, and a capacitor of the piezoelectric unit are analyzed so as to calculate a characteristic resonant frequency having the same characteristic as that of the first driving frequency (step S430).

At this time, when the first resonant frequency is changed due to changes in surrounding environment and temperature, the characteristic resonant frequency is changed by the same width, because the characteristic resonant frequency has the same characteristic as the first resonant frequency.

Accordingly, the delta frequency is added to the calculated characteristic resonant frequency so as to calculate an optimal driving frequency for the piezoelectric unit (step S440). Then, as the calculated optimal driving frequency is supplied to the piezoelectric unit, the piezoelectric unit resonates at the maximum. Therefore, the lens section can be moved the maximum distance by the piezoelectric unit.

In the method for searching for an optimal driving frequency using a piezoelectric actuator, when the resonant frequency of the piezoelectric element is changed depending on changes in surrounding environment and temperature, the constant delta frequency is added to the characteristic resonant frequency which is changed by the same width as the resonant frequency of the piezoelectric unit, thereby calculating the optimal driving frequency. Therefore, the piezoelectric unit can always resonate at the maximum despite the changes in surrounding environment and temperature.

According to the present invention, the characteristics of the resistor, the inductor, and the capacitor of the piezoelectric unit are analyzed so as to calculate the same characteristic resonant frequency as the first resonant frequency of the piezoelectric unit. Therefore, it is possible to drive the piezoelectric unit in a constant manner despite the changes in surrounding environment and temperature.

Further, since the piezoelectric actuator is composed of only the optimal driving frequency calculating unit and the FM modulating unit, it is possible to reduce the size of the circuit.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A piezoelectric actuator for driving a piezoelectric unit having two resonance points, the piezoelectric actuator comprising:
an optimal driving frequency calculating unit that adds a delta frequency, having a constant frequency difference from a first resonant frequency of the piezoelectric unit, to a characteristic resonant frequency obtained by analyzing characteristics of the piezoelectric unit, thereby calculating an optimal driving frequency; and
an FM modulating unit that is connected to the optimal driving frequency calculating unit and generates the optimal driving frequency, calculated by the optimal driving frequency calculating unit, so as to supply to the piezoelectric unit.

2. The piezoelectric actuator according to claim 1, wherein the characteristic resonant frequency is calculated by analyzing the characteristics of a resistor, an inductor, and a capacitor of the piezoelectric unit.

3. The piezoelectric actuator according to claim 1, wherein the characteristic resonant frequency of the optimal driving frequency calculating unit has the same characteristic as that of the first resonant frequency of the piezoelectric unit.

4. The piezoelectric actuator according to claim 1, wherein the delta frequency is obtained by subtracting the first resonant frequency from an intermediate frequency between the first and second resonant frequencies of the piezoelectric unit.

5. A method for searching for an optimal driving frequency for driving a piezoelectric unit having two resonance points, the method comprising the steps of:
(a) calculating an intermediate frequency between first and second resonant frequencies of the piezoelectric unit;
(b) calculating a delta frequency by subtracting the first frequency from the calculated intermediate frequency;
(c) calculating a characteristic resonant frequency by analyzing characteristics of the piezoelectric unit; and
(d) calculating an optimal driving frequency by adding the delta frequency to the characteristic resonant frequency calculated in step (c).

6. The method according to claim 5, wherein in step (c), the characteristics of a resistor, an inductor, and a capacitor of the piezoelectric unit are analyzed.

7. The method according to claim 5, wherein the characteristic resonant frequency calculated in step (c) has the same characteristic as the first resonant frequency of the piezoelectric unit.
